(19) United States
(12) Patent Application Publication
(10) Pub. No.: US 2025/0015114 A1
(43) Pub. Date: Jan. 9, 2025

(54) IMAGE SENSOR AND MANUFACTURING METHOD OF IMAGE SENSOR

(71) Applicant: SAMSUNG ELECTRONICS CO., LTD., Suwon-si (KR)

(72) Inventors: Sanghoon LEE, Suwon-si (KR); Jingyun Kim, Suwon-si (KR); Seunghyun Lee, Suwon-si (KR); Soojin Hong, Suown-si (KR)

(73) Assignee: SAMSUNG ELECTRONICS CO., LTD., Suwon-si (KR)

(21) Appl. No.: 18/431,548

(22) Filed: Feb. 2, 2024

(30) Foreign Application Priority Data
Jul. 7, 2023 (KR) 10-2023-0088234

(51) Int. Cl. H01L 27/146

(52) U.S. Cl. CPC H01L 27/1463; H01L 27/14645; H01L 27/14689

(57) ABSTRACT

An image sensor according to an embodiment includes a substrate having first and second surfaces facing each other, separated by a deep trench, and including a plurality of pixel regions; a plurality of photoelectric conversion regions disposed in the plurality of pixel regions; a blocking region disposed in the plurality of pixel regions; and a plurality of color filters and a plurality of micro lenses disposed on the second surface of the substrate. The blocking region is disposed adjacent to the second surface of the substrate, the blocking region includes a first element of a first type, and the plurality of photoelectric conversion regions include a second element of a second type different from the first type. The concentration of the first element on the second surface of the substrate in the blocking region is about 1E16/cm³ to about 1E18/cm³.

### CROSS-REFERENCE TO RELATED APPLICATION

This application claims priority to and the benefit of Korean Patent Application No. 10-2023-0088234 filed in the Korean Intellectual Property Office on Jul. 7, 2023, the entire contents of which are incorporated herein by reference.

### BACKGROUND

### 1. Field

The disclosure relates to an image sensor and a manufacturing method of the image sensor.

### 2. Description of the Related Art

Complementary metal-oxide semiconductor (CMOS) image sensors are solid-state imaging devices that use complementary metal-oxide semiconductors. CMOS image sensors have lower manufacturing costs compared to CCD image sensors. In addition, CMOS image sensors have smaller size compared to CCD image sensors having a high-voltage analog circuit, and thus, consume less power. As a result, CMOS image sensors are frequently used for electronic appliances including portable devices such as smartphones and digital cameras.

A pixel array included in a CMOS image sensor includes a photoelectric conversion element in each pixel. The photoelectric conversion element may generate an electrical signal that varies based on the quantity of incident light. The CMOS image sensor may process the electrical signal to synthesize an image.

When metal particles generated in a manufacturing process are introduced to a photoelectric conversion element such as photodiodes, leakage currents can occur, resulting in performance degradation of a photodiode, which may cause performance degradation of CMOS image sensors.

### SUMMARY

Example embodiments of the disclosure provide an image sensor and a manufacturing method of the image sensor that may avoid or reduce performance degradation, such as leakage current of a photodiode, which may occur due to fine particles generated during a manufacturing process.

However, embodiments of the disclosure are not limited to those mentioned above, and may be variously extended in the scope of the technical ideas included in the disclosure.

An image sensor according to an aspect of an example embodiment includes a substrate having a first surface and a second surface facing the first surface, the substrate including a plurality of pixel regions separated by a deep trench, the plurality of pixel regions being adjacent to each other along a first direction and a second direction; a plurality of photoelectric conversion regions disposed in the plurality of pixel regions; a blocking region disposed in the plurality of pixel regions; a plurality of wiring layers and a plurality of insulating layers disposed on the first surface of the substrate; and a plurality of color filters and a plurality of micro lenses disposed on the second surface of the substrate, wherein the blocking region is disposed adjacent to the second surface of the substrate, wherein the blocking region includes a first element of a first type, and the plurality of photoelectric conversion regions include a second element of a second type, the second type being different from the first type, and wherein a concentration of the first element in the blocking region on the second surface of the substrate is about 1E16/cm³ to about 1E18/cm³.

A method of manufacturing an image sensor according to an aspect of an example embodiment includes forming a plurality of deep trenches that divide a plurality of adjacent pixel regions along a first direction and a second direction from a first surface of a substrate toward an inside of the substrate, implanting a first element of a first type from the first surface of the substrate by using a first high-energy implant method to form a blocking region, and implanting a second element of a second type from the first surface of the substrate by using a second high-energy implant method to form a plurality of photoelectric conversion regions, wherein the plurality of photoelectric conversion regions are disposed on the blocking region along a third direction, the third direction being vertical to the first direction and the second direction and toward the first surface of the substrate.

According to embodiments, it is possible to provide an image sensor and a manufacturing method of the image sensor capable of preventing or reducing performance degradation, such as leakage current of a photodiode, which may occur due to fine particles generated during a manufacturing process of the image sensor.

However, it will be appreciated that the effects of embodiments are not limited to those described above and may be expanded in various ways without departing from the spirit and scope of the disclosure.

### BRIEF DESCRIPTION OF DRAWINGS

The above and/or other aspects will be more apparent from the following description of example embodiments taken in conjunction with the accompanying drawings.

FIG. 1 is a block diagram schematically illustrating an image sensor according to an embodiment.

FIG. 2 is a plan view illustrating a part of an image sensor according to an embodiment.

FIG. 3 is a top plan view schematically illustrating an image sensor according to an embodiment.

FIG. 4 is a cross-sectional view taken along the line I-I′ of FIG. 3.

FIG. 5 is a cross-sectional view of an image sensor according to an embodiment.

FIG. 6 to FIG. 9, FIG. 11 to FIG. 12, and FIG. 14 to FIG. 15 are cross-sectional views illustrating a manufacturing method of an image sensor according to an embodiment.

FIG. 10 and FIG. 13 are graphs illustrating examples of ion implantation energy and ion concentration in a manufacturing method of an image sensor according to an embodiment.

FIG. 16 is a cross-sectional view illustrating a manufacturing method of an image sensor according to an embodiment.

FIG. 17 and FIG. 18 are graphs illustrating the result of an experimental example.

### DETAILED DESCRIPTION

Hereinafter, the disclosure will be described in detail hereinafter with reference to the accompanying drawings, in which example embodiments of the disclosure are shown. As those skilled in the art would understand, the described example embodiments may be modified in various different ways, all without departing from the spirit or scope of the disclosure.

The drawings and description are to be regarded as illustrative in nature and not restrictive. Like reference numerals designate like elements throughout the specification.

The accompanying drawings are intended only to facilitate an understanding of the example embodiments disclosed in this specification, and it is to be understood that the technical ideas disclosed herein are not limited by the accompanying drawings and include all modifications, equivalents, or substitutions that are within the range of the ideas and technology of the disclosure.

Size and thickness of each constituent element in the drawings are arbitrarily illustrated for better understanding and ease of description, and the example embodiments are not limited thereto. In the drawings, the thickness of layers, films, panels, regions, etc., may be exaggerated for clarity. In the drawings, the thickness of some layers and regions may be exaggerated for ease of description.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity.

Further, in addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Throughout the specification, the term “connected” does not mean only that two or more constituent components are directly connected, but may also mean that two or more constituent components are indirectly connected through another constituent component, that two or more components are electrically connected as well as physically connected, or that two or more constituent components are referred to by different names but are united by location or function.

Hereinafter, various example embodiments and variations will be described in detail with reference to the drawings.

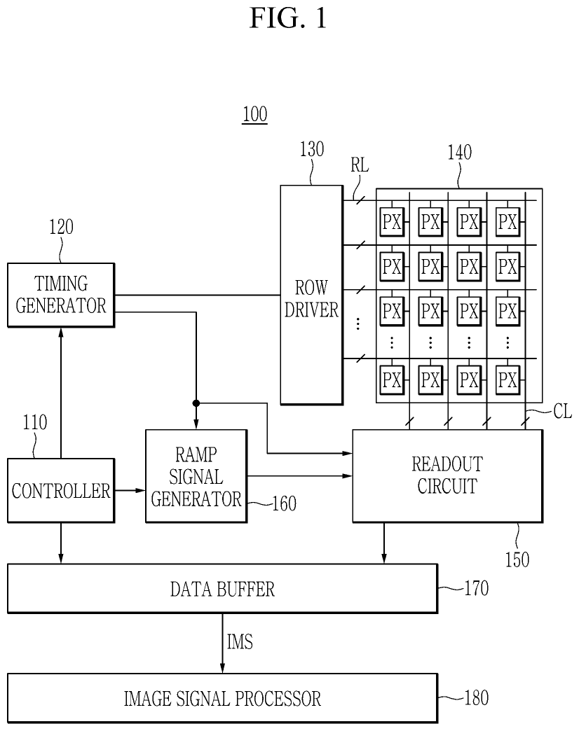

Referring to FIG. 1, an image sensor according to an embodiment will be schematically described. FIG. 1 is a block diagram schematically illustrating an image sensor according to an embodiment.

Referring to FIG. 1, an image sensor 100 according to an embodiment may include a pixel array 140 and a logic circuit configured to control the pixel array 140.

The logic circuit is a circuit configured to control the pixel array 140, and may include, for example, a controller 110, a timing generator 120, a row driver 130, a readout circuit 150, a ramp signal generator 160, a data buffer 170, and the like.

The image sensor 100 may further include an image signal processor 180. According to another embodiment, the image signal processor 180 may be disposed outside the image sensor 100. The image sensor 100 may generate an image signal by converting light received from the outside into an electrical signal. The image signal may be provided to the image signal processor 180.

The image sensor 100 may be mounted on an electronic device having an image sensing function or a light sensing function. For example, the image sensor 100 may be mounted on an electronic device such as a camera, smart phone, wearable device, Internet of Things (IoT) device, home appliance, tablet personal computer (PC), navigation, drone, advanced driver assistance system (ADAS), and the like. In addition, the image sensor 100 may be mounted on electronic devices provided as components of vehicles, furniture, manufacturing facilities, doors, various measuring devices, and the like.

The pixel array 140 may include a plurality of pixels PX, a plurality of row lines RL respectively connected to the plurality of pixels PX, and a plurality of column lines CL.

In one embodiment, each pixel PX may include at least one photoelectric conversion element. The photoelectric conversion element may sense incident light and convert the incident light into an electrical signal according to the quantity of sensed incident light. Thus, the photoelectric conversion elements of the plurality of pixels PX may output a plurality of analog pixel signals.

The photoelectric conversion element may be a photodiode, a pinned diode, or the like. In addition, the photoelectric conversion element may be a single-photon avalanche diode (SPAD) applied to a 3D sensor pixel.

The level of the analog pixel signal output from the photoelectric conversion element may be proportional to the quantity of charge output from the photoelectric conversion element. That is, the level of the analog pixel signal output from the photoelectric conversion element may be determined according to the quantity of light received at the pixel array 140.

The plurality of row lines RL may be connected to the plurality of pixels PX. For example, a control signal output from the row driver 130 to a row line RL may be transmitted to gates of transistors of the plurality of pixels PX connected to the corresponding row line RL. A column line CL is disposed to cross a row line RL and may be connected to the plurality of pixels PX. The plurality of pixel signals output from the plurality of pixels PX may be transmitted to the readout circuit 150 through the plurality of column lines CL.

The controller 110 may control the operation timing of each of the above-mentioned constituent elements 120, 130, 150, 160, and 170 using control signals.

In an embodiment, the controller 110 may receive a mode signal indicating an imaging mode from an application processor, and overall control the image sensor 100 based on the received mode signal. For example, the application processor may determine an imaging mode of the image sensor 100 according to various scenarios, such as the illumination of an imaging environment, a user's resolution setting, and/or a sensed or learned state, and may provide the determined result to the controller 110 as a mode signal.

The controller 110 may control the plurality of pixels PX of the pixel array 140 to output pixel signals according to the imaging mode. The pixel array 140 may output a pixel signal for each of the plurality of pixels PX or a pixel signal for some of the plurality of pixels PX. The readout circuit 150 may sample and process the pixel signals received from the pixel array 140.

The timing generator 120 may generate a signal serving as a reference for operation timing of elements of the image sensor 100. The timing generator 120 may control timing of the row driver 130, the readout circuit 150, and the ramp signal generator 160. The timing generator 120 may provide control signals controlling timing of the row driver 130, the readout circuit 150, and the ramp signal generator 160.

The row driver 130 may generate a control signal for driving the pixel array 140 in response to a control signal of the timing generator 120, and may provide the control signal to the plurality of pixels PX of the pixel array 140 through the plurality of row lines RL.

In an embodiment, the row driver 130 may control the pixel PX to sense incident light in row line units. A row line unit may include at least one row line RL. For example, the row driver 130 may generate a transmission signal for controlling a transmission transistor, a reset control signal for controlling a reset transistor, and a selection control signal for controlling a selection transistor, and provide the generated signals to the pixel array 140.

The readout circuit 150 may convert a pixel signal (or electric signal) from the pixel PX, selected from among the plurality of pixels PX and connected to the row line RL, into a pixel value representing the quantity of light in response to a control signal from the timing generator 120.

The readout circuit 150 may convert a pixel signal output through a corresponding column line CL into a pixel value. For example, the readout circuit 150 may convert a pixel signal into a pixel value by comparing the ramp signal and the pixel signal. The pixel value may be image data having a plurality of bits. Specifically, the readout circuit 150 may include a selector, a plurality of comparators, and a plurality of counter circuits.

The ramp signal generator 160 may generate a reference signal and transmit the reference signal to the readout circuit 150. The ramp signal generator 160 may include a current source, a resistor, and a capacitor. The ramp signal generator 160 may adjust the ramp voltage applied to the ramp resistance by controlling the current value of the variable current source or the resistance value of the variable resistor. Accordingly, the ramp signal generator 160 may generate a plurality of ramp signals that fall or rise with a slope determined according to the current value of the variable current source or the resistance value of the variable resistor.

The data buffer 170 may store pixel values of the plurality of pixels PX connected to the selected column line CL transmitted from the readout circuit 150, and output the stored pixel values in response to an enable signal from the controller 110.

The image signal processor 180 may perform image signal processing on the image signal received from the data buffer 170. For example, the image signal processor 180 may receive a plurality of image signals from the data buffer 170, and generate an image by synthesizing the received image signals.

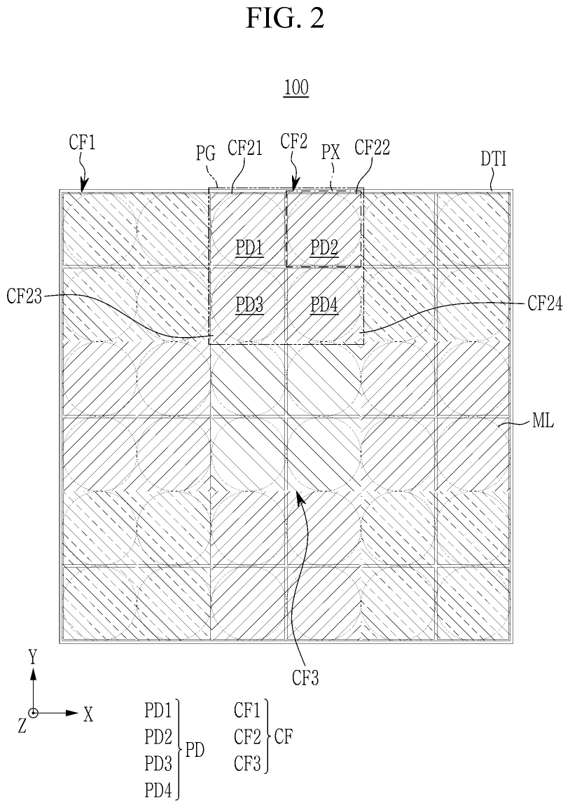

Referring to FIG. 2, a pixel arrangement of an image sensor according to an embodiment will be described. FIG. 2 is a plan view illustrating a part of an image sensor according to an embodiment.

Referring to FIG. 2, the image sensor 100 according to an embodiment may include pixel groups PG, photodiodes PD, color filters CF, micro lenses ML, and other circuits required for operation of the image sensor 100.

The plurality of pixels PX may be grouped in a plurality of columns and a plurality of rows to form one unit pixel group PG.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M matrix form. N and M may each independently be an integer greater than 1. For example, each of N and M may be 2, and the pixel group PG may have a pixel arrangement having 2×2 tetra structure in a plan view. That is, each of the plurality of pixel groups PG may include pixels PX arranged in a 2×2 form in a plan view.

More specifically, the plurality of pixels PX arranged in a direction of the column line CL and the plurality of pixels PX arranged in a direction of the row line RL may configure one unit of pixel group PG. For example, one unit of pixel group PG may include a plurality of pixels PX arranged in two columns and two rows, and one unit of pixel group PG may output one analog pixel signal. However, the embodiment is not limited thereto, and the number of pixels PX included in one pixel group PG may be variously modified.

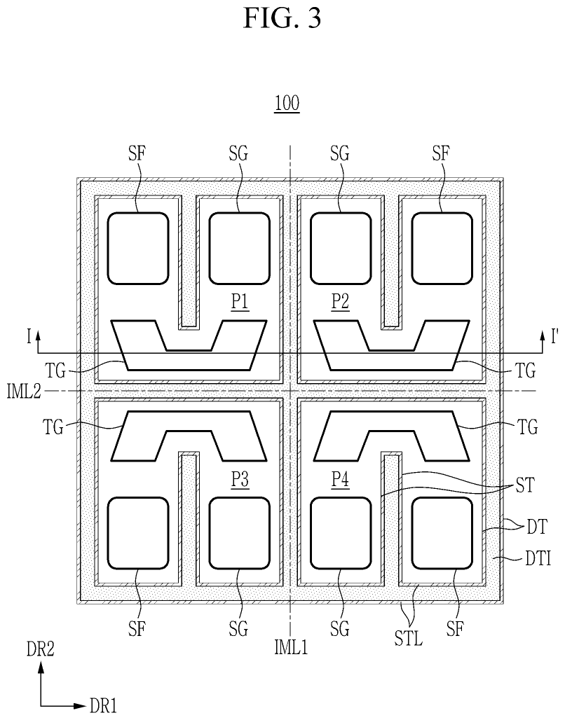

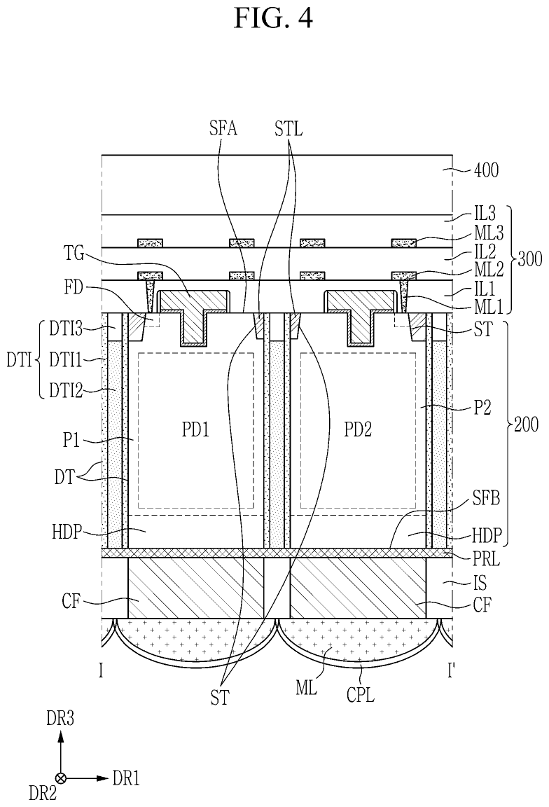

Referring to FIGS. 3 and 4, an image sensor according to an embodiment will be described in more detail. FIG. 3 is a top plan view schematically illustrating an image sensor according to an embodiment, and FIG. 4 is a cross-sectional view taken along the line I-I′ of FIG. 3.

Referring to FIG. 3, the image sensor 100 according to an embodiment may include a plurality of pixels P1, P2, P3, and P4. The plurality of pixels P1, P2, P3, and P4 may include a first pixel P1, a second pixel P2, a third pixel P3, and a fourth pixel P4 adjacent to each other along a first direction DR1 and a second direction DR2 different from the first direction DR1.

On a plane defined by the first and second directions DR1 and DR2, the first pixel P1 and the second pixel P2 may be disposed adjacent to each other, and the third pixel P3 and the fourth pixel P4 may be disposed adjacent to each other, along the first direction DR1. In addition, on the plane defined by the first and second directions DR1 and DR2, the first pixel P1 and the third pixel P3 may be disposed adjacent to each other and the second pixel P2 and the fourth pixel P4 may be disposed adjacent to each other, along the second direction DR2.

The plurality of pixels P1, P2, P3, and P4 may be separated from each other by a pixel isolation structure DTI. The pixel isolation structure DTI may be connected to each other and disposed to surround the first pixel P1, the second pixel P2, the third pixel P3, and the fourth pixel P4, respectively. The pixel isolation structure DTI may prevent crosstalk between the plurality of pixels P1, P2, P3, and P4.

The pixel isolation structure DTI may be disposed in a deep trench DT, and at least a portion of the deep trench DT may be surrounded by a device isolation layer STL disposed in a shallow trench ST.

Each of the plurality of pixels P1, P2, P3, and P4 may include a plurality of gates TG, SF, SG, and RG (not shown). The plurality of gates TG, SF, SG, and RG may include a transfer gate TG, a drive gate SF, a selection gate SG, and a reset gate RG.

In an embodiment, the plurality of gates TG, SF, SG, and RG of the first pixel P1 may be symmetrical to the plurality of gates TG, SF, SG, and RG of the second pixel P2 based on a first imaginary line IML1 which is parallel to the second direction DR2 and passing between the first pixel P1 and the second pixel P2. Similarly, the plurality of gates TG, SF, SG, and RG of the third pixel P3 may be symmetrical to the plurality of gates TG, SF, SG, and RG of the fourth pixel P4 based on the first imaginary line IML1.

Further, the plurality of gates TG, SF, SG, and RG of the first pixel P1 may be symmetrical to the plurality of gates TG, SF, SG, and RG of the third pixel P3 based on the imaginary second line IML2 which is parallel to the first direction DR1 and passing between the first pixel P1 and the third pixel P3. Similarly, the plurality of gates TG, SF, SG, and RG of the second pixel P2 may be symmetrical to the plurality of gates TG, SF, SG, and RG of the fourth pixel P4 based on the second imaginary line IML2.

Referring to FIG. 4 together with FIGS. 1 to 3, the image sensor 100 may include a substrate 200. The substrate 200 may include, for example but not limited to, silicon (Si), germanium (Ge), or silicon (Si)-germanium (Ge). The substrate 200 may include gallium arsenide (GaAs), indium phosphide (InP), gallium phosphide (GaP), indium arsenide (InAs), indium antimony (InSb), or indium gallium arsenide (InGaAs). The substrate 200 may include zinc telluride (ZnTe) or cadmium sulfide (CdS).

The substrate 200 may be a bulk silicon or silicon-on-insulator (SOI). The substrate 200 may be a silicon substrate, or may include other material such as, for example but not limited to, silicon germanium, indium antimonide, lead telluride compound, indium arsenide, indium phosphide, gallium arsenide, or gallium antimonide. In another implementation, the substrate 200 may be a base substrate having an epitaxial layer formed thereon.

The substrate 200 may include a first surface SFA and a second surface SFB facing each other.

The substrate 200 includes a deep trench DT, and a pixel isolation structure DTI may be disposed in the deep trench DT of the substrate 200. As described above, the pixel isolation structure DTI surrounds the pixels P1, P2, P3, and P4, and the plurality of pixels P1, P2, P3, and P4 may be separated from each other by the pixel isolation structure DTI.

The deep trench DT and the pixel isolation structure DTI may be disposed to penetrate the substrate 200 from the first surface SFA to the second surface SFB of the substrate 200. Thus, the depth of the deep trench DT along the height direction, which is a third direction DR3, may be substantially equal to the thickness of the substrate 200.

The pixel isolation structure DTI may include an insulating pattern DTI, a conductive pattern DTI2, and a capping pattern DTI3. The insulating pattern DTI1 may cover inner walls of the deep trench DT. The capping pattern DTI3 may fill an upper portion of the deep trench DT. The conductive pattern DTI2 may fill a lower portion of the deep trench DT. An upper surface of the capping pattern DTI3 may be coplanar with the first surface SFA of the substrate 200, and a lower surface of the conductive pattern DTI2 may be coplanar with the second surface SFB of the substrate 200. The insulating pattern DTI1 may extend from the first surface SFA to the second surface SFB of the substrate 200. The conductive pattern DTI2 may be separated from other portions of the substrate 200 by the insulating pattern DTI1. In another embodiment, the capping pattern DTI3 may be omitted.

The conductive pattern DTI2 may include, for example, a semiconductor material such as n-type or p-type doped polysilicon or a metal material. The insulating pattern DTI1 and the capping pattern DTI3 may include silicon oxide, silicon nitride, or silicon oxynitride. The insulating pattern DTI1 may include a metal oxide such as hafnium oxide, aluminum oxide, or tantalum oxide. In this case, the insulating pattern DTI1 may function as a negative fixed charge layer.

A blocking region HDP may be disposed in a region adjacent to the second surface SFB of the substrate 200.

The blocking region HDP may be doped with an impurity different from that of the photoelectric conversion regions PD1, PD2, PD3, and PD4. For example, the blocking region HDP may be doped with a first element, which may be a P-type impurity. The blocking region HDP may be adjacent to the second surface SFB of the substrate 200, and the concentration of the first element in the blocking region HDP may be higher than the concentration of the first element of other regions of the substrate 200.

The first element may include boron-11 (11 Boron). A concentration of boron-11 on the second surface SFB of the substrate 200 in the blocking region HDP may be about 1 E16/cm³ to about 1 E18/cm³. The blocking region HDP may have a thickness of about 250 nm to about 2000 nm.

The first element may be implanted into the blocking region HDP using a high-energy implant method.

In this case, the implant energy intensity may be about 2.5 MeV to about 6.5 MeV, the implant dose may be about 5E12/cm² to about 1 E14/cm², and the tilt angle when implanting impurities may be about 0 degree to about 7 degrees. The implant dose may be the number of impurity elements implanted into the surface of the substrate 200 per unit area (1 cm²).

The blocking regions HDP corresponding to the pixels P1, P2, P3, and P4 may be separated from each other by the pixel isolation structure DTI.

The photoelectric conversion regions PD1, PD2, PD3, and PD4 corresponding to the respective pixels P1, P2, P3, and P4 may be disposed in the substrate 200.

The photoelectric conversion regions PD1, PD2, PD3, and PD4 may be disposed on the blocking region HDP along the third direction DR3, which is the height direction.

Light incident from the outside may be converted into electrical signals in the photoelectric conversion regions PD1, PD2, PD3, and PD4. The photoelectric conversion regions PD1, PD2, PD3, and PD4 may include photodiodes formed inside the substrate 200. The photoelectric conversion regions PD1, PD2, PD3, and PD4 may be doped with a conductive impurity different from the conductive impurity doped in the substrate 200, and the photoelectric conversion regions PD1, PD2, PD3, and PD4 may be doped with a different type of impurity from the impurity doped in the blocking region HDP.

A pixel isolation structure DTI may be disposed between the photoelectric conversion regions PD1, PD2, PD3, and PD4 corresponding to the plurality of pixels P1, P2, P3, and P4, such that the photoelectric conversion regions PD1, PD2, PD3, and PD4 corresponding to the plurality of pixels P1, P2, P3, and P4 may be separated from each other by the pixel isolation structure DTI. The pixel isolation structure DTI may be used to electrically and optically isolate adjacent photoelectric conversion regions PD1, PD2, PD3, and PD4 from each other.

The substrate 200 includes the shallow trench ST, and the device isolation layer STL may be disposed in the shallow trench ST of the substrate 200. The shallow trench ST may be disposed on a portion of the substrate 200 adjacent to the first surface SFA of the substrate 200 without penetrating the substrate 200.

A depth of the shallow trench ST may be smaller than a depth of the deep trench DT along the third direction DR3, which is the height direction.

An upper surface of the device isolation layer STL may be coplanar with the first surface SFA of the substrate 200. The device isolation layer STL may include silicon oxide, silicon nitride, or any combination thereof.

A plurality of gates TG, SF, SG, and RG may be disposed on the first surface SFA of the substrate 200.

The substrate 200 may have a plurality of floating diffusion regions FD and a plurality of ground regions (not shown) disposed adjacent to the first surface SFA.

The plurality of floating diffusion regions FD may be adjacent to each of the transfer gates TG. The plurality of floating diffusion regions FD may have a conductivity type opposite to the conductivity type of the substrate 200.

The plurality of ground regions may be doped with conductive impurities, such as the conductive impurities doped in the substrate 200, and the concentration of the doped conductive impurities may be higher than the concentration of other regions of the substrate 200.

Although not shown, the substrate 200 may further include a plurality of impurity regions disposed adjacent to the first surface SFA, and the plurality of impurity regions may be active regions for operating transistors.

The plurality of ground regions, the plurality of gates TG, SF, SG, and RG, and the floating diffusion region FD may form a transfer transistor, a drive transistor, a selection transistor, and a reset transistor. The plurality of ground regions may be ground patterns for grounding at least one of a transfer transistor, a drive transistor, a selection transistor, and a reset transistor.

A first structure 300 may be disposed on the first surface SFA of the substrate 200. The first structure 300 may include a plurality of vias ML1, a plurality of wiring layers ML2 and ML3, and a plurality of insulating layers IL1, IL2 and IL3. The plurality of insulating layers IL1, IL2 and IL3 may electrically separate the plurality of vias ML1 and the plurality of wiring layers ML2 and ML3.

The plurality of vias ML1 and the plurality of wiring layers ML2 and ML3 may be electrically connected to transistors on the first surface SFA of the substrate 200.

The plurality of vias ML1 and the plurality of wiring layers ML2 and ML3 may include, for example but not limited to, tungsten, aluminum, copper, tungsten silicide, titanium silicide, tungsten nitride, titanium nitride, doped polysilicon, or the like.

The plurality of insulating layers IL1, IL2, and IL3 may include an insulating material such as, for example but not limited to, silicon oxide, silicon nitride, silicon oxynitride, or a low-k material. The low-k dielectric material may include, for example but not limited to, at least one of flowable oxide (FOX), torene silazene (TOSZ), undoped silica glass (USG), borosilica glass (BSG), phosphosilica glass (PSG), borophosphosilica glass (BPSG), plasma enhanced tetraethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, or porous polymeric material, and any combination thereof.

The image sensor 100 may further include a support substrate 400 disposed on the first structure 300. In one embodiment, the support substrate 400 may be omitted. An adhesive member (not shown) may be further disposed between the support substrate 400 and the first structure 300.

An anti-reflection layer PRL may be disposed on the second surface SFB of the substrate 200. The anti-reflection layer PRL may cover the second surface SFB of the substrate 200 and the pixel isolation structure DTI.

The anti-reflection layer PRL may include, for example but not limited to, hafnium oxide (HfO2), silicon oxide (SiO₂), silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), yttrium oxide (Y₂O₃), or any combination thereof.

In an embodiment, the anti-reflection layer PRL may include a plurality of layers including different materials and having different thicknesses. For example, the anti-reflective layer PRL may include first to third anti-reflective layers sequentially stacked on the second surface SFB of the substrate 200.

The first anti-reflection layer may be a fixed charge layer having a negative fixed charge. Hole accumulation may occur in the periphery of the fixed charge layer. Thus, it is possible to effectively reduce a dark current and a white spot.

The third anti-reflection layer may include a metal oxide or metal fluoride including, for example but not limited to, at least one of hafnium (Hf), zirconium (Zr), aluminum (AI), tantalum (Ta), titanium (Ti), and yttrium (Y). For example, the first anti-reflection layer and the third anti-reflection layer may include a hafnium oxide layer, and the second anti-reflection layer may include silicon oxide and/or silicon nitride. However, in another embodiment, the number and relative thickness of the layers included in the anti-reflection layer PRL may be variously modified.

In addition, in another embodiment, the anti-reflection layer PRL may further include a silicon nitride layer disposed between the second anti-reflection layer and the third anti-reflection layer.

Fence patterns IS may be disposed under the anti-reflection layer PRL. On a plane formed by the first and third directions DR1 and DR3, the fence patterns IS may extend along a portion of the pixel isolation structure DTI, and a portion of the pixel isolation structure DTI may overlap the fence patterns IS along a third direction DR3, which is a height direction.

The fence patterns IS may surround the color filters CF.

The fence patterns IS may include a low refractive index material. A low refractive index material may have a refractive index greater than about 1.0 and less than or equal to about 1.4. For example, the low refractive index material may include, for example but not limited to, polymethylmethacrylate (PMMA), silicon acrylate (silicon acrylate), cellulose acetatebutyrate (CAB), silica, or fluoro-silicon acrylate (FSA). For example, the low refractive index material may include a polymer material in which silica (SiOx) particles are dispersed.

When the fence patterns IS include a low refractive index material having a relatively low refractive index, light incident toward the fence patterns IS may be totally reflected and directed toward the center of each of the pixel regions P1, P2, P3, and P4.

The fence patterns IS may prevent light obliquely incident into the color filter CF disposed in one of the plurality of pixel regions P1, P2, P3, and P4 from entering the color filter CF disposed in another adjacent pixel region. Accordingly, crosstalk between the plurality of pixel regions P1 to P4 may be prevented.

The plurality of color filters CF may be disposed on the anti-reflection layer PRL and may be separated from each other by the fence pattern IS. The plurality of color filters CF may include, for example, a green filter, a blue filter, and a red filter. The plurality of color filters CF may include, for example, cyan, magenta, or yellow.

The micro lens ML may be disposed on the color filter CF and the fence pattern IS. On a plane formed by the first and second directions DR1 and DR2, the micro lenses ML may be disposed to correspond to the plurality of pixel regions P1, P2, P3, and P4, respectively.

The micro lens ML may be transparent. The micro lens ML may be made of a resin-based material such as, for example, a styrene-based resin, an acryl-based resin, a styrene-acrylic copolymer resin, or a siloxane-based resin.

The micro lens ML condenses incident light, and the condensed light may be incident to the photoelectric conversion regions PD1, PD2, PD3, and PD4 through the color filter CF.

A capping layer CPL may be disposed on the micro lens ML to protect the micro lens ML.

As described above, the blocking region HDP may be disposed between the photoelectric conversion regions PD1, PD2, PD3, and PD4 of each pixel P1, P2, P3, and P4 separated by the deep trench DT and the pixel isolation structure DTI penetrating the substrate 200 from the first surface SFA to the second surface SFB of the substrate 200.

The blocking region HDP of each pixel P1, P2, P3, and P4 may be ion-implanted with an element of a different type from the element of the photoelectric conversion regions PD1, PD2, PD3, and PD4.

During the manufacturing process of the image sensor 100, when the first structure 300 is provided on the first surface SFA of the substrate 200, and the anti-reflection layer PRL, the fence patterns IS, the color filters CF, and micro lens ML are formed on the second surface SFB of the substrate 200, unnecessary conductive particles may be generated. According to the disclosure, even if unnecessary conductive particles generated during the manufacturing process may induce leakage current, the influence of the leakage current caused by these unnecessary conductive particles may not be diffused to the photoelectric conversion regions PD1, PD2, PD3, and PD4 due to the blocking region HDP doped with the first element of a different type from the element of the photoelectric conversion regions PD1, PD2, PD3, and PD4.

The blocking region HDP may be a region in which the first element is implanted by a high-energy implant method, and the blocking region HDP may be doped with boron-11 (11Boron).

The blocking region HDP is doped with the first element by a high-energy implant method, such that the first element may be implanted through the first surface SFA of the substrate 200. Accordingly, the blocking region HDP may be formed before forming the photoelectric conversion regions PD1, PD2, PD3, and PD4. As such, after forming the blocking region HDP adjacent to the second surface SFB of the substrate 200, the photoelectric conversion regions PD1, PD2, PD3, and PD4 is formed on the substrate 200; the first structure 300 is provided to the first surface SFA of the substrate 200, and the anti-reflection layer PRL, the fence patterns IS, and the color filters CF, and the micro lens ML are provided on the second surface SFB of the substrate 200. Accordingly, by using the blocking region HDP, it is possible to prevent the influence of leakage current that may be caused by unnecessary particles generated in a subsequent process from diffusing to the photoelectric conversion regions PD1, PD2, PD3, and PD4.

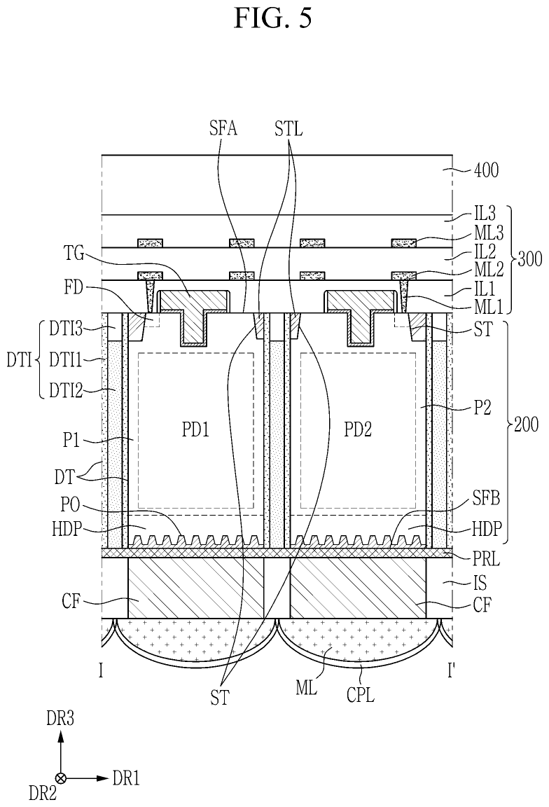

Referring to FIG. 5 together with FIGS. 1 to 4, an image sensor 101 according to another embodiment will be described. FIG. 5 is a cross-sectional view of an image sensor according to another embodiment.

Referring to FIG. 5, the image sensor 101 according to this embodiment is similar to the image sensor 100 according to the above-described embodiment. A detailed description of the same component is omitted.

Referring to FIG. 5, the image sensor 101 according to the present embodiment includes the plurality of pixels P1, P2, P3, and P4 including the first pixel P1, the second pixel P2, the third pixel P3, and the fourth pixel P4 adjacent to each other along the first and second directions DR1 and DR2, and the plurality of pixels P1, P2, P3, and P4 may be separated by the deep trench DT and the pixel isolation structure DTI penetrating the substrate 200 from the first surface SFA to the second surface SFB of the substrate 200.

The plurality of pixels P1, P2, P3, and P4 may include the blocking region HDP and the photoelectric conversion regions PD1, PD2, PD3, and PD4 doped with different impurities.

For example, the blocking region HDP may be doped with a first element, which is a P-type impurity. The blocking region HDP may be adjacent to the second surface SFB of the substrate 200, and the concentration of the first element in the blocking region HDP may be higher than the concentration of the first element of other regions of the substrate 200.

The blocking region HDP may be doped with boron-11 (11Boron). The concentration of boron-11 on the second surface SFB of the substrate 200 in the blocking region HDP may be 1E16/cm³ to 1E18/cm³. The blocking region HDP may have a thickness of about 250 nm to about 2000 nm.

The first element may be implanted into the blocking region HDP using a high-energy implant method.

In this case, the implant energy intensity may be about 2.5 MeV to about 6.5 MeV, the implant dose may be about 5E12/cm² to about 1 E14/cm², and the tilt angle when implanting ion may be about 0 degree to about 7 degrees.

The blocking regions HDP corresponding to the pixels P1, P2, P3, and P4 may be separated from each other by the pixel isolation structure DTI.

Unlike the image sensor 100 according to the above-described embodiment, in the image sensor 101 according to the present embodiment, a fine pattern layer PO may be disposed between the blocking region HDP and the anti-reflection layer PRL. The fine pattern layer PO may include a plurality of protruding portions.

The fine pattern layer PO allows light incident through the second surface SFB of the substrate 200 to be refracted toward the photoelectric conversion regions PD1, PD2, PD3, and PD4, thereby preventing the incident light from being reflected to the outside and increasing the efficiency of light incident to the photoelectric conversion regions PD1, PD2, PD3, and PD4.

By positioning the plurality of fine pattern layers PO on the second surface SFB of the substrate 200, the area of the interface between the second surface SFB of the substrate 200 and the plurality of fine pattern layers PO is widened, so that the influence of leakage current caused by unnecessary fine particles generated at the interface may be easily diffused to the photoelectric conversion regions PD1, PD2, PD3, and PD4.

In addition, unnecessary fine particles may be generated when forming the plurality of fine pattern layers PO, and an influence such as leakage current caused by these unnecessary fine particles may be diffused to the photoelectric conversion regions PD1, PD2, PD3, and PD4.

However, the image sensor 101 according to the embodiment may include the blocking region HDP, which is disposed between the photoelectric conversion regions PD1, PD2, PD3, and PD4 of each pixel P1, P2, P3, and P4 separated by the deep trench DT and the pixel isolation structure DTI penetrating the substrate 200 from the first surface SFA to the second surface SFB of the substrate 200.

The blocking region HDP of each pixel P1, P2, P3, and P4 may be ion-implanted with an element of a different type from the element of the photoelectric conversion regions PD1, PD2, PD3, and PD4.

During the manufacturing process of the image sensor 100, when the first structure 300 is provided to the first surface SFA of the substrate 200, and the fine pattern layer PO, the anti-reflection layer PRL, the fence patterns IS, the color filters CF, and the micro lens ML are formed on the second surface SFB of the substrate 200, unnecessary conductive particles may be generated. Unnecessary conductive particles generated during the manufacturing process may induce leakage current. However, according to the disclosure, the leakage current caused by these unnecessary conductive particles may not influence the photoelectric conversion regions PD1, PD2, PD3, and PD4 due to the blocking region HDP doped with the first element of a different type from the element of the photoelectric conversion regions PD1, PD2, PD3, and PD4.

The blocking region HDP may be a region in which the first element is implanted by a high-energy implant method, and the blocking region HDP may be doped with boron-11 (11 Boron).

The blocking region HDP is doped with the first element by a high-energy implant method, such that the first element may be implanted through the first surface SFA of the substrate 200. Accordingly, the blocking region HDP may be formed before forming the photoelectric conversion regions PD1, PD2, PD3, and PD4. As such, after forming the blocking region HDP on the second surface SFB of the substrate 200, the photoelectric conversion regions PD1, PD2, PD3, and PD4 are formed on the substrate 200; the first structure 300 is provided to the first surface SFA of the substrate 200; and the fine pattern layer PO, the anti-reflection layer PRL, the fence patterns IS, the color filters CF, and the micro lens ML are formed on the second surface SFB of the substrate 200. Accordingly, by using the blocking region HDP, it is possible to prevent the influence of leakage current caused by unnecessary particles generated in a subsequent process from diffusing to the photoelectric conversion regions PD1, PD2, PD3, and PD4.

Many features of the image sensor 100 according to the above-described embodiment are all applicable to the image sensor 101 according to the present embodiment.

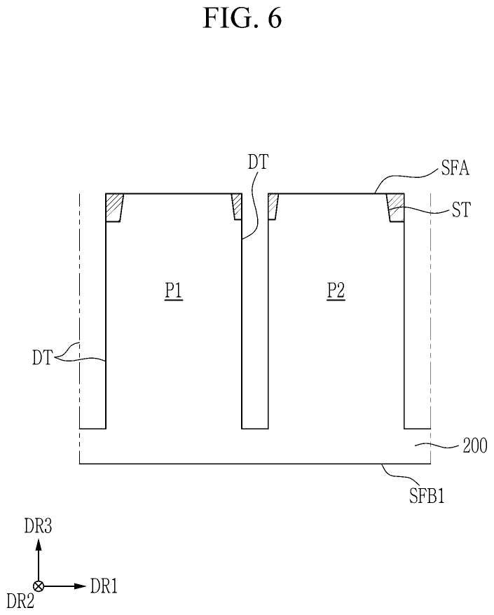

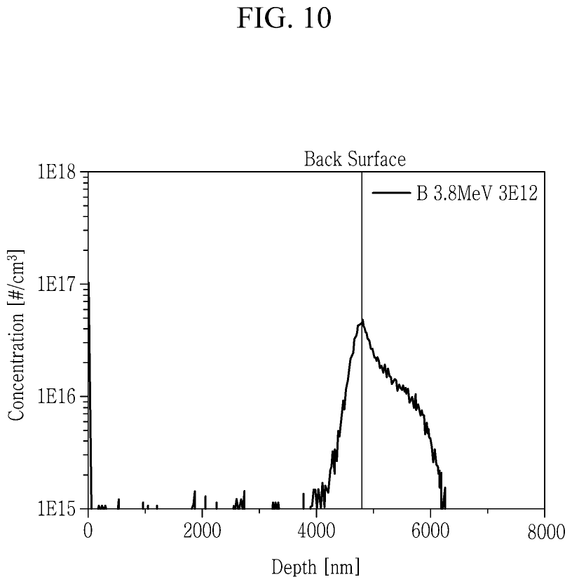

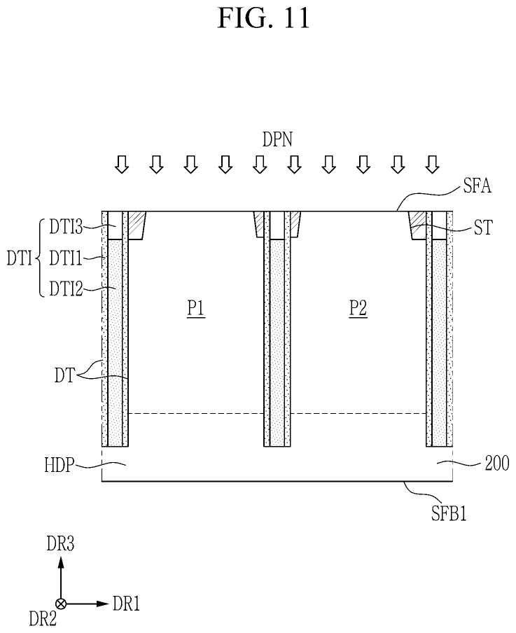

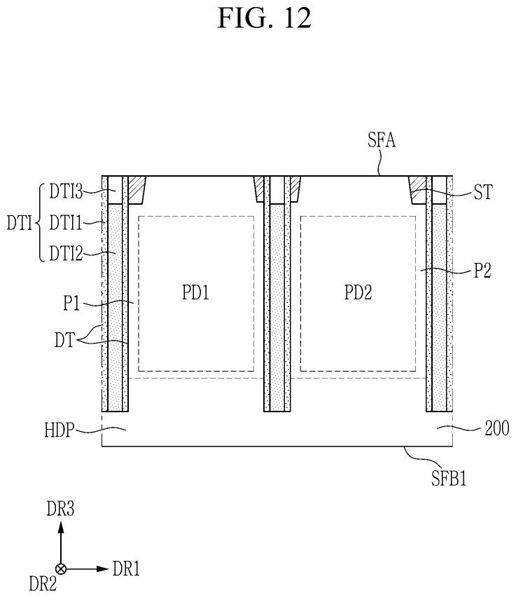

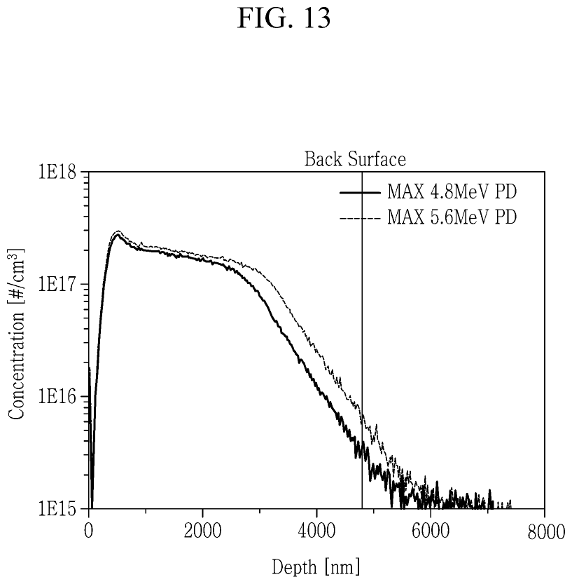

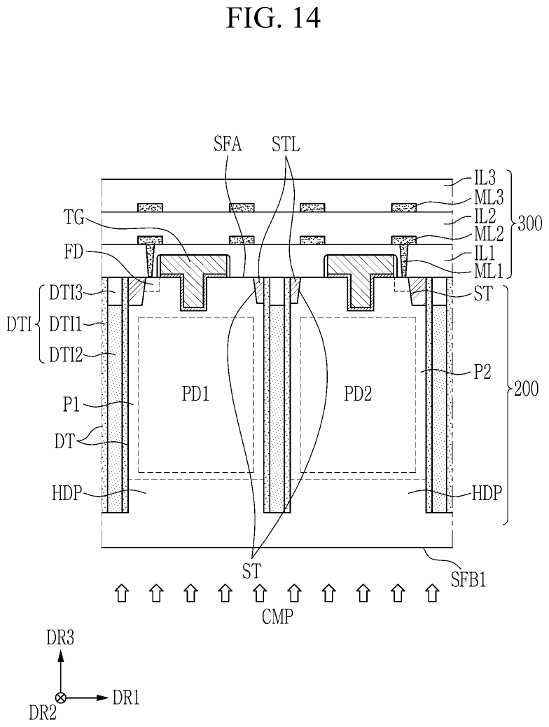

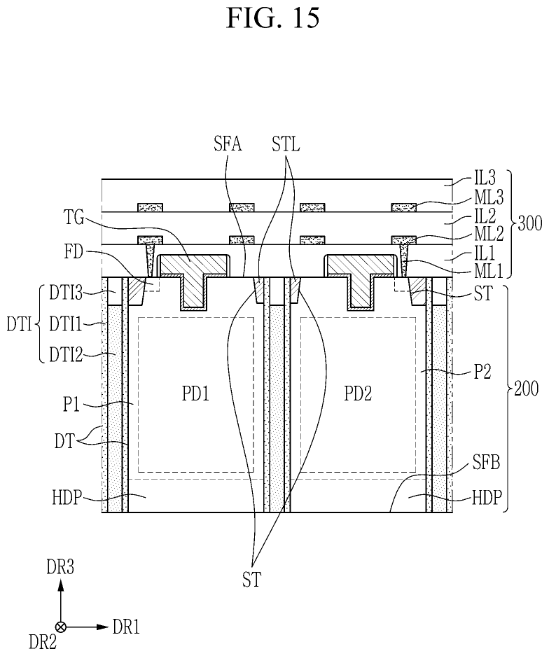

A manufacturing method of an image sensor according to an embodiment will be described with reference to FIGS. 6 to 15 along with FIGS. 3 and 4. FIG. 6 to FIG. 9, FIG. 11 to FIG. 12, and FIG. 14 to FIG. 15 are cross-sectional views illustrating a manufacturing method of an image sensor according to an embodiment, and FIG. 10 and FIG. 13 are graphs illustrating examples of ion implantation energy and ion concentration in a manufacturing method of an image sensor according to an embodiment.

Referring to FIG. 6, the deep trench DT may be formed from the first surface SFA of the substrate 200 toward a preliminary surface SFB1 of the substrate 200. The deep trench DT may be formed in the device isolation layer STL formed in the shallow trench ST and in the substrate 200.

The deep trench DT may be formed to separate pixels P1, P2, P3, and P4.

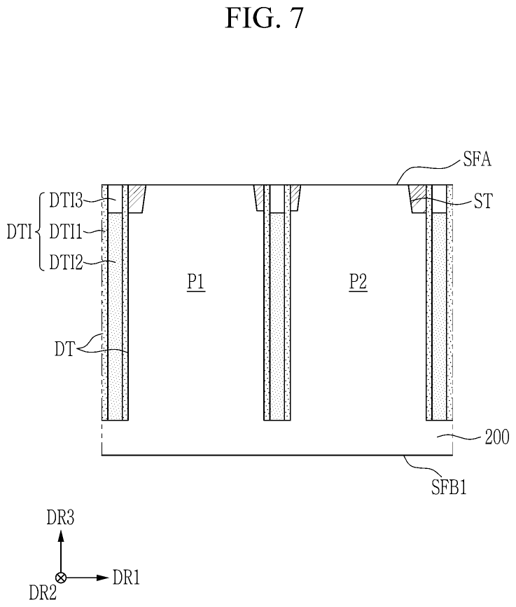

Referring to FIG. 7, the pixel isolation structure DTI may be formed in the deep trench DT of the substrate 200. The pixel isolation structure DTI may include the insulating pattern DTI1, the conductive pattern DTI2, and the capping pattern DTI3.

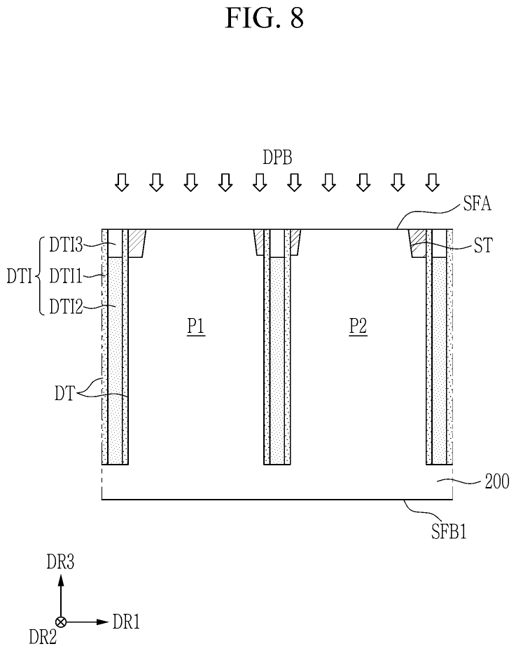

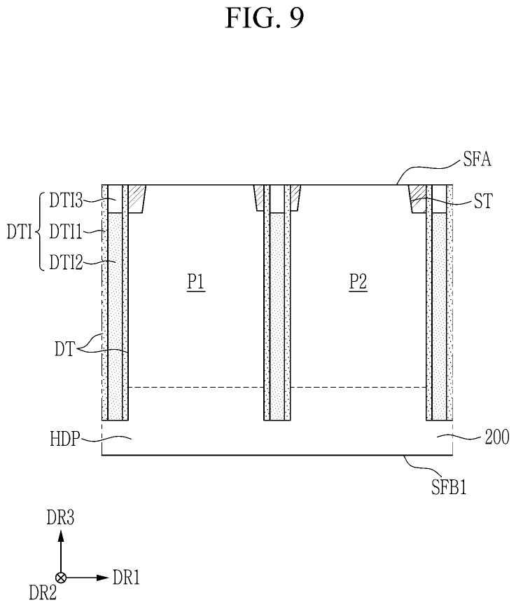

Referring to FIG. 8, by implanting a first element of a first type from the first surface SFA of the substrate 200 toward the preliminary surface SFB1 of the substrate 200 by a high-energy implant method (denoted by “DPB”), the blocking region HDP having a high concentration of the first element may be formed on the lower side of the pixel isolation structure DTI in the deep trench DT of the substrate 200 and the preliminary surface SFB1 of the substrate 200, as shown in FIG. 9.

The first element may be boron-11 (11 Boron). When implanting the first element (“DPB” in FIG. 8), the implantation energy intensity may be about 2.5 MeV to about 5.0 MeV, the implant dose may be about 1 E12/cm² to about 1 E14/cm², and the tilt angle when implanting ion may be about 2 degrees to about 7 degrees.

The first element may be implanted into a region separated by the pixel isolation structure DTI in the trench DT and below the pixel isolation structure DTI.

The concentration of the first element may be relatively high in the trench DT on the lower side of the pixel isolation structure DTI, and the concentration of the first element on the lower side of the pixel isolation structure DTI may be from about 1 E16/cm³ to about 1 E18/cm³.

Referring to FIG. 10, when the implant energy of boron-11 (11Boron) is about 3.8 MeV and the implant dose is about 3E12/cm², boron-11 may be implanted at a depth of about 4000 nm to about 6000 nm from the first surface SFA of the substrate 200. For example, the concentration of boron-11 (11 Boron) at a position from about 4700 nm to about 4800 nm may be higher than the concentration of boron-11 at other regions, and may be from about 1E16/cm³ to about 1E17/cm³.

As such, the impurities may be implanted to have a higher concentration on the preliminary surface SFB1 of the substrate 200 facing the first surface SFA than on the first surface SFA of the substrate 200 to which ion implant is applied, by adjusting the implant energy and implant dose of the impurities according to the thickness of the substrate 200.

Next, as shown in FIG. 11, by implanting a second element of a second type different from the first type from the first surface SFA of the substrate 200 toward the preliminary surface SFB1 of the substrate 200 by a high-energy implant method (denoted by “DPN”), the photoelectric conversion regions PD1, PD2, PD3, and PD4 corresponding to the pixels P1, P2, P3, and P4 separated by the pixel isolation structure DTI in the deep trench DT of the substrate 200 may be formed.

Referring to FIG. 13, when the maximum implant energy of the second element are about 4.8 MeV and about 5.6 MeV, the second element may be implanted at a depth of about 6000 nm from the first surface SFA of the substrate 200. As such, by adjusting the implant energy and the implant dose of the impurity according to the thickness of the substrate 200, the impurity may be implanted to have a desired concentration at a desired depth from the first surface SFA of the substrate 200.

Referring to FIG. 14, by providing the first structure 300 to the first surface SFA of the substrate 200 and removing a part of the substrate 200 through a chemical physical polishing process (CMP), the second surface SFB of the substrate 200 may be formed to be coplanar with the deep trench DT and the pixel isolation structure DTI, as shown in FIG. 15.

Although not shown in FIGS. 14 and 15, the support substrate 400 may be further provided to the first structure 300.

Next, the image sensor 100 of FIGS. 3 and 4 may be formed by forming the anti-reflection layer PRL, the fence patterns IS, the color filters CF, and the micro lens ML on the second surface SFB of the substrate 200.

As described above, according to the manufacturing method of the image sensor according to the present embodiment, the first element is implanted by using a high-energy implant method, and accordingly, the blocking region HDP may be formed before the photoelectric conversion regions PD1, PD2, PD3, and PD4 are formed. As such, after forming the blocking region HDP on the second surface SFB of the substrate 200, the photoelectric conversion regions PD1, PD2, PD3, and PD4 are formed on the substrate 200; the first structure 300 is provided to the first surface SFA of the substrate 200; and the anti-reflection layer PRL, the fence patterns IS, and the color filters CF, and the micro lens ML are formed. Accordingly, by using the blocking region HDP, it is possible to prevent the influence of leakage current caused by unnecessary particles generated in a subsequent process from diffusing to the photoelectric conversion regions PD1, PD2, PD3, and PD4.

In addition, it is possible to prevent the first structure 300 from being damaged on the first surface SFA of the substrate 200 by the high-energy ion implant process for forming the blocking region HDP.

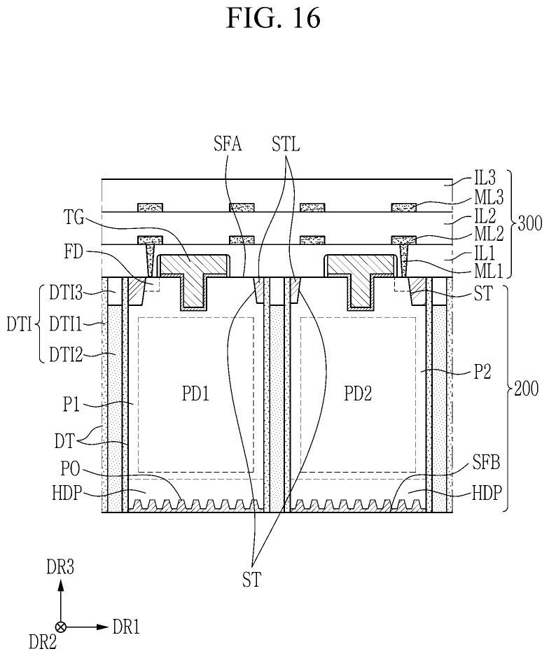

Then, referring to FIG. 16 along with FIGS. 4 to 15, a manufacturing method of an image sensor according to another embodiment will be described. FIG. 16 is a cross-sectional view illustrating a manufacturing method of an image sensor according to another embodiment.

As shown in FIGS. 6 to 15, in the manufacturing method of the image sensor according to the present embodiment, the deep trench DT may be formed from the first surface SFA of the substrate 200 toward the preliminary surface SFB1 of the substrate 200, the pixel isolation structure DTI may be formed in the deep trench DT of the substrate 200, and the blocking region HDP with a high concentration of the first element may be formed on the lower side of the pixel isolation structure DTI in the deep trench DT of the substrate 200 and the preliminary surface SFB1 of the substrate 200 by implanting the first element of the first type from the first surface SFA of the substrate 200 toward the preliminary surface SFB1 of the substrate 200 by using a high-energy implant method (“DPB”). Next, the photoelectric conversion regions PD1, PD2, PD3, and PD4 corresponding to the pixels P1, P2, P3, and P4 separated by the pixel isolation structure DTI in the deep trench DT of the substrate 200 may be formed by implanting the second element of the second type different from the first type from the first surface SFA of the substrate 200 toward the preliminary surface SFB1 of the substrate 200 by using a high-energy implant method (“DPN”), the second surface SFB of the substrate 200 may be formed to be coplanar with the deep trench DT and the pixel isolation structure DTI by removing a part of the substrate 200 through a chemical physical polishing process (CMP), and the first structure 300 may be provided to the first surface SFA of the substrate 200.

After that, as shown in FIG. 16, the fine pattern layer PO may be formed on the second surface SFB of the substrate 200. The fine pattern layer PO may include a plurality of fine patterns protruding toward the photoelectric conversion regions PD1, PD2, PD3, and PD4.

Subsequently, the image sensor 101 of FIG. 5 may be formed by forming the anti-reflection layer PRL, the fence patterns IS, the color filters CF, and the micro lens ML on the fine pattern layer PO of the second surface SFB of the substrate 200.

As described above, according to the manufacturing method of the image sensor according to the present embodiment, the blocking region HDP may be formed by implanting the first element by using a high-energy implant method before the photoelectric conversion regions PD1, PD2, PD3, and PD4 are formed. As such, after forming the blocking region HDP on the second surface SFB of the substrate 200, the photoelectric conversion regions PD1, PD2, PD3, and PD4 are formed on the substrate 200; the first structure 300 is provided to the first surface SFA of the substrate 200; and the fine pattern layer PO, the anti-reflection layer PRL, the fence patterns IS, the color filters CF, and the micro lens ML are formed on the second surface SFB of the substrate 200. Accordingly, by using the blocking region HDP, it is possible to prevent the influence of leakage current caused by unnecessary particles generated in a subsequent process from diffusing to the photoelectric conversion regions PD1, PD2, PD3, and PD4.

In addition, it is possible to prevent the first structure 300 from being damaged on the first surface SFA of the substrate 200 by forming the blocking region HDP using the high-energy ion implant process before the first structure 300 is provided to the first surface SFA.

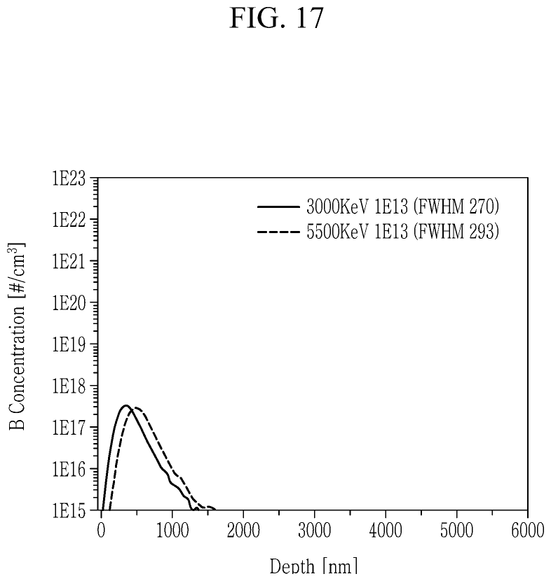

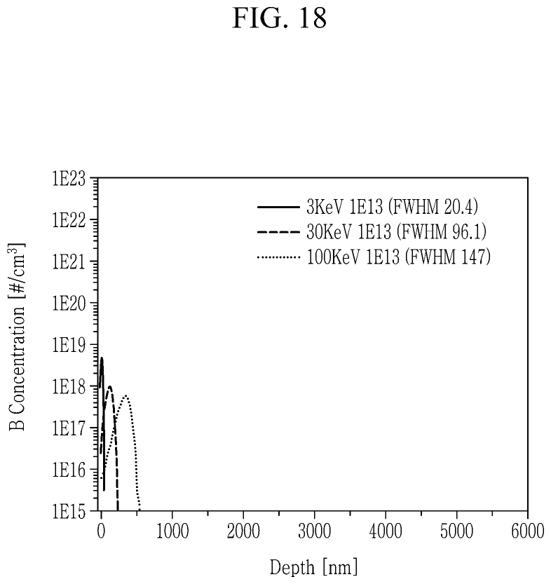

An experimental example will be described with reference to FIGS. 17 and 18. FIG. 17 and FIG. 18 are graphs illustrating results of experimental examples.

In these experimental examples, the depth of the boron-11 (11 Boron) implanted layer was measured while changing the energy of the boron-11 (11 Boron) implant. At this time, the implant dose was constant at 1E13/cm².

More specifically, the results of high-energy implant of boron-11 with an implant energy of about 3000 keV and boron-11 with an implant energy of about 5500 keV are shown in FIG. 17, and the results of low-energy implant of boron-11 with an implant energy of about 3 keV, about 30 keV, and about 100 keV are shown in FIG. 18.

Referring to FIGS. 17 and 18, it can be seen that the depth of full width at half maximum (FWHM) of boron-11 (11Boron) was relatively deep, 250 nm or more, when the high-energy implant was performed with the implant energy of boron-11 (11 Boron) of about 3000 keV and or 5500 keV. In the case of low-energy implant, where the injection energy is about 3 KeV, about 30 KeV, and about 100 KeV, the depth of full width at half maximum (FWHM) of Boron-11 (11Boron) was relatively shallow, less than or equal to about 150 nm.

As such, it can be seen that when the first element is implanted by a high-energy implant method, as in the manufacturing method of the image sensor according to the embodiment, the blocking region HDP having a thickness of about 250 nm or more may be formed.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims and their equivalents.

What is claimed is:

1. An image sensor, comprising:
a substrate having a first surface and a second surface facing the first surface, the substrate including a plurality of pixel regions separated by a deep trench, the plurality of pixel regions being adjacent to each other along a first direction and a second direction;
a plurality of photoelectric conversion regions disposed in the plurality of pixel regions;
a blocking region disposed in the plurality of pixel regions;
a plurality of wiring layers and a plurality of insulating layers disposed on the first surface of the substrate; and
a plurality of color filters and a plurality of micro lenses disposed on the second surface of the substrate,
wherein the blocking region is disposed adjacent to the second surface of the substrate,
wherein the blocking region includes a first element of a first type, and the plurality of photoelectric conversion regions include a second element of a second type, the second type being different from the first type, and
wherein a concentration of the first element in the blocking region on the second surface of the substrate is about 1 E16/cm³ to about 1 E18/cm³.

2. The image sensor of claim 1, wherein:
the first element includes boron-11 (11 Boron).

3. The image sensor of claim 2, wherein:
the blocking region has a thickness of about 250 nm to about 2000 nm along a third direction, the third direction being vertical to the first direction and the second direction and directed from the second surface of the substrate to the first surface of the substrate.

4. The image sensor of claim 1, wherein:
the deep trench penetrates from the first surface toward the second surface of the substrate.

5. The image sensor of claim 4, further comprising:
a pixel isolation structure disposed within the deep trench,
wherein an upper surface of the pixel isolation structure is coplanar with the first surface of the substrate, and a lower surface of the pixel isolation structure is coplanar with the second surface of the substrate, along a third direction, the third direction being vertical to the first direction and the second direction.

6. The image sensor of claim 1, wherein:
the blocking region includes a plurality of blocking regions separated by the pixel isolation structure, the plurality of blocking regions corresponding to the plurality of pixel regions, respectively.

7. The image sensor of claim 6, wherein:
the plurality of photoelectric conversion regions are disposed on the plurality of blocking regions along a third direction, the third direction being vertical to the first direction and the second direction and directed from the second surface of the substrate to the first surface.

8. The image sensor of claim 1, wherein:
the first element is a P-type, and the second element is an N-type.

9. The image sensor of claim 8, wherein:
the first element includes boron-11 (11 Boron).

10. The image sensor of claim 1, further comprising:
a fine pattern layer including a plurality of protruding portions and disposed below the blocking region along a third direction, the third direction being vertical to the first direction and the second direction and directed from the second surface of the substrate to the first surface.

11. A method of manufacturing an image sensor, the method comprising:
forming a plurality of deep trenches that divide a plurality of adjacent pixel regions along a first direction and a second direction from a first surface of a substrate toward an inside of the substrate;
implanting a first element of a first type from the first surface of the substrate by using a first high-energy implant method, to form a blocking region; and
implanting a second element of a second type from the first surface of the substrate by using a second high-energy implant method, to form a plurality of photoelectric conversion regions,
wherein the plurality of photoelectric conversion regions are disposed on the blocking region along a third direction, the third direction being vertical to the first direction and the second direction and toward the first surface of the substrate.

12. The method of claim 11, wherein:
the first element includes boron-11 (11 Boron).

13. The method of claim 12, wherein:
an energy intensity of the first high-energy implant method is about 2.5 MeV to about 6.5 MeV.

14. The method of claim 13, wherein:
an implant dose of the first high-energy implant method is about 5E12/cm² to about 1E14/cm².

15. The method of claim 14, wherein:
a tilt angle of the first high-energy implant method is about 0 degree to about 7 degrees.

16. The method of claim 11, further comprising:
forming a plurality of pixel isolation structures within the plurality of deep trenches of the substrate; and
forming a second surface of the substrate by polishing a surface that is opposite to the first surface of the substrate,
wherein an upper surface of the pixel isolation structure is coplanar with the first surface of the substrate, and a lower surface of the pixel isolation structure is coplanar with the second surface of the substrate, along the third direction.

17. The method of claim 16, wherein:
the blocking region includes a plurality of blocking regions, the plurality of blocking regions being separated by the pixel isolation structure and corresponding to the plurality of pixel regions.

18. The method of claim 16, wherein:
a concentration of the first element in the blocking region on the second surface of the substrate is about 1 E16/cm³ to about 1 E18/cm³.

19. The method of claim 11, wherein:
the first element implanted into the blocking region is a P-type, and the second element implanted into the plurality of photoelectric conversion regions is an N-type.

20. The method of claim 11, wherein:
the blocking region has a thickness of about 250 nm to about 2000 nm, along the third direction.
